(19) United States
(12) Patent Application Publication
(10) Pub. No.: US 2016/0156339 A1
(43) Pub. Date: Jun. 2, 2016

(54) APPARATUS AND METHOD FOR GENERATING HIGH-VOLTAGE PULSES

(71) Applicant: SIEMENS AKTIENGESELLSCHAFT, München (DE)

(72) Inventors: Werner HARTMANN, Weisendorf (DE); Martin HERGT, Nuremberg (DE)

(73) Assignee: SIEMENS AKTIENGESELLSCHAFT, München (DE)

(21) Appl. No.: 14/786,423

(22) PCT Filed: Mar. 5, 2014
(86) PCT No.: PCT/EP2014/054203

§ 371 Date: Oct. 22, 2015

(30) Foreign Application Priority Data
Apr. 23, 2013 (DE) 10 2013 207 328.3

(51) Int. Cl. H03K 3/53

(52) U.S. Cl. CPC H03K 3/53

(57) ABSTRACT

The present invention relates to an apparatus for generating high-voltage pulses, in particular by means of an inductive coltage adder (IVA), wherein an inner conductor (1) of a coaxial transmission line (21) is in the form of a body which is rotationally symmetrical to a main axis (HA) of wave propogation and passes through all stages, the outer radius of said body being formed so as to decrease in size continuously from the first to the last stage with a constant pitch.

The invention relates to an apparatus for generating high-voltage pulses according to the preamble of the main claim and to a corresponding method according to the coordinate claim.

In electrical engineering, high-voltage and high-power pulses of between a few kW and several hundred TW in amplitude are used for scientific and industrial purposes in the field of pulsed power engineering, with pulse durations being in the range of ps to ms.

What is known as electroporation, which is cited here as an example of an industrial application, requires a pulse generator that can generate voltages of 250 kV, currents of a few 10 kA with a pulse duration of between 1 μs and 2 μs, for example.

A possible topology for implementing such a pulse generator is what is known as an “inductive voltage adder”, which is abbreviated to IVA. Such a generator allows a compact design, since during pulse generation it is made up of a series circuit comprising n discrete voltage sources. In physical terms, in a conductor geometry called a transformer, the electromagnetic fields are combined in the IVA.

In this way, the transformer essentially determines the design of an IVA (inductive voltage adder).

The transformer is made up of a coaxial transmission line and a radial transmission line, the radial transmission line being connected to the outer conductor of the coaxial transmission line at right angles. Such a topology allows the electric fields in the transformer to be added vectorially and hence summation of the voltage amplitudes to be achieved. As a result of the high-frequency pulse, the characteristic impedances need to be attuned to one another in order to avoid reflections.

To avoid reflections during voltage addition, selection of a correct characteristic impedance is necessary. Conventionally, the coaxial transmission line is of cascaded design, with the individual stages merging into one another by means of what are known as tapers. Such tapers are necessary in order to avoid transition points over the electromagnetic wave that is to be generated.

“Pulsed Power Systems Principles and Applications” by Hans-joachim Bluhm; Springer Verlag Berlin Heidelberg 2006 discloses conventional inductive voltage adders IVAs, particularly in chapter 7, pages 192-201, design and operating principles of IVAs.

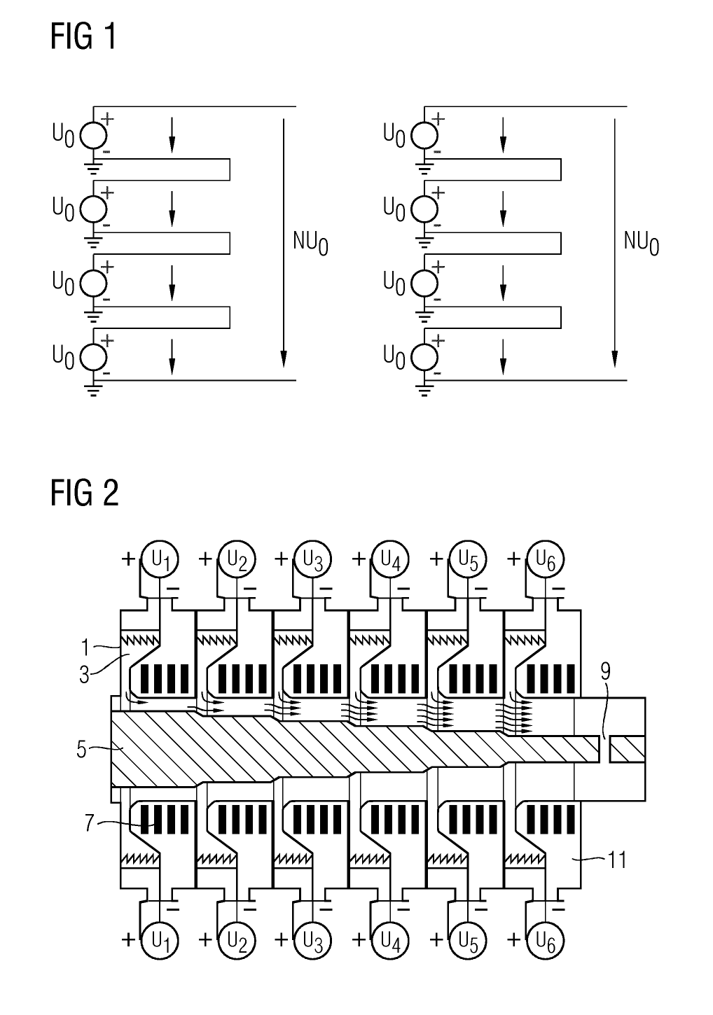

An IVA allows the use of the wave properties, as a result of the reflection factors, during the switch-on process and in the steady state to increase the current amplitude. FIG. 1 shows the conventional principle of an IVA. FIG. 1 shows the basic principle of the IVA using the example of four stages. In a similar manner to in the case of a serial arrangement of voltage sources, which are shown on the left-hand side in FIG. 1, pulse lines, as are shown on the right-hand side of FIG. 1, can be implemented as voltage multiplier circuits by connecting the positive conductor of one line to the negative conductor of the other. So that this alternate connection of the conductors does not produce a short, the connection needs to be insulated for the duration of the pulse. This can be achieved using sufficiently long transmission lines, in the form of a cable transformer, or by virtue of the coupling to sufficiently high coupling inductances, in line with the embodiment of an IVA. A more compact design is possible if, instead of the propagation time, inductive insulation is used for the addition of the pulse lines of individual stages. The principle of voltage addition using magnetic insulation, as per the IVA, is shown in FIG. 2.

FIG. 2 shows a conventional exemplary embodiment of an IVA with magnetic insulation. FIG. 2 shows six stages which are arranged coaxially. Reference symbol 1 denotes a vacuum interface, reference symbol 3 denotes a vacuum, reference symbol 5 denotes an annular gap, reference symbol 7 denotes a magnetic core, reference symbol 9 denotes a diode and reference symbol 11 denotes oil. The cylindrical cavities form an inner conductor of the IVA and are fed radially by conventional, coaxially arranged voltage sources Ux. In the case of the applications described, each of the individual cavities delivers a pulse with a duration of between 0.1 and 50 μs, for example, with a voltage amplitude U₀ of a few kV, for example in the range from 3 to 10 kV, and a maximum current amplitude I₀ of between a few kA and >10 kA, for example. In order to prompt addition of the voltage amplitudes, the vector addition of the electromagnetic fields in the transition region to the coaxial transmission line is exploited. The IVA thus generates a voltage pulse that is overlaid on itself from the sum of the n (n: number of stages) individual voltage sources. Accordingly, an arrangement as shown in FIG. 2 generates a sextuple voltage pulse. In order to prompt the addition of the voltage amplitudes, the positive conductor of one voltage source is connected to the negative conductor of the subsequent voltage sources. This necessarily produces a conductive connection in each cavity between the center electrode and the outer electrode situated downstream. In order to prevent a short from arising in the output of the line in this way, the impedance of the connection is greatly enhanced by increasing the relative permeability in this section. To this end, a partial volume of the voltage source is filled with toroidal strip cores made of ferromagnetic material.

It is an object of the present invention to provide an apparatus and a method for producing high-voltage pulses that involve the use of a pulse generator that is more compact and less expensive in comparison with the prior art. The aim is to bring about the most reflection-free wave coupling possible.

The object is achieved by an apparatus according to the main claim and a method according to the coordinate claim.

According to a first aspect, an apparatus for generating high-voltage pulses, particularly an inductive voltage adder, is claimed, wherein during the pulse generation there is combination of electromagnetic fields from a series circuit comprising a number n of discrete stages, arranged along a wave propagation main axis, of voltage sources in a transformer, with waves respectively propagating along a radial transmission line into a coaxial transmission line in each stage, characterized in that the inner conductor of the coaxial transmission line is in the form of a body that is rotationally symmetrical with respect to the wave propagation main axis, passes through all the stages and the outer radius of which is designed to decrease continuously with a constant slope from the first to the last stage.

According to a second aspect, a method for generating high-voltage pulses, particularly an inductive voltage adder, is claimed, wherein during the pulse generation there is combination of electromagnetic fields from a series circuit comprising a number n of discrete stages, arranged along a wave propagation main axis, of voltage sources in a transformer, with waves respectively propagating along a radial transmission line into a coaxial transmission line in each stage, characterized in that the inner conductor of the coaxial transmission line is in the form of a body that is rotationally symmetrical with respect to the wave propagation main axis, passes through all the stages and the outer radius of which is designed to decrease continuously with a constant slope from the first to the last stage.

According to the invention, a pulse generator is produced and used that is able to be made as compact and inexpensive as possible.

The wave propagation main axis is situated on the common axis of the inner and outer conductors of the coaxial transmission line. The direction of the wave propagation main axis corresponds to the direction in which the waves from the IVA actually propagate. The wave propagation main axis is similarly an axis of symmetry with respect to which parts of the IVA are rotationally symmetrical, for example the inner and outer conductors of the coaxial transmission line.

According to the inventive embodiment of an IVA, the following advantages are obtained:
simpler manufacturing in comparison with a conventional, cascaded coaxial inner conductor.
Lower costs for manufacturing the inner conductor, as a result of simpler manufacturing technology.
A higher withstand voltage, as a result of smaller electric fields on the conical, coaxial inner conductor.
Lower attenuation losses in the transformer for high-frequency signal components.

Further advantageous embodiments are claimed in conjunction with the subclaims.

According to one advantageous embodiment, the inner conductor can have an external geometric shape of a straight truncated cone or cone. The inner conductor can be provided as a solid body without interior spaces.

According to a further advantageous embodiment, the inner conductor can be in the form of a cone.

According to a further advantageous embodiment, the outer conductor of the coaxial transmission line can be in the form of a hollow body that is rotationally symmetrical with respect to the wave propagation main axis, is invariably provided discretely in a stage and the outer radii and inner radii of which are the same and constant for all the stages.

According to a further advantageous embodiment, the hollow bodies each can have a geometric shape of a hollow cylinder. The outer conductor runs coaxially with respect to the inner conductor, in particular. That is to say that the outer and inner conductors have a common axis with respect to which they are rotationally symmetrical, in particular.

According to a further advantageous embodiment, the radial and coaxial transmission lines can have the same material, particularly copper, steel or aluminum.

According to a further advantageous embodiment, all n stages can have a like modular design in respect to the electrical interconnections of said stages.

The invention is described in more detail with the aid of exemplary embodiments in conjunction with the figures, in which:

FIG. 1 shows a conventional exemplary embodiment of an IVA;

FIG. 2 shows a further conventional exemplary embodiment of an IVA;

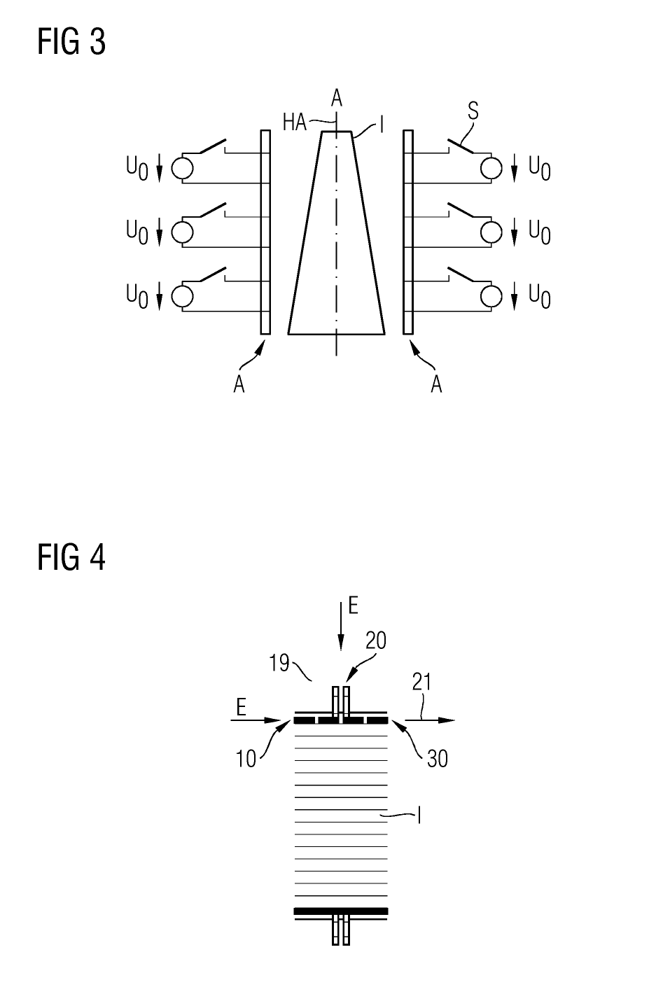

FIG. 3 shows an inventive exemplary embodiment of an IVA;

FIG. 4 shows a representation to simulate the inventive exemplary embodiment of the IVA;

FIG. 5 shows a further representation to simulate the inventive exemplary embodiment of the IVA;

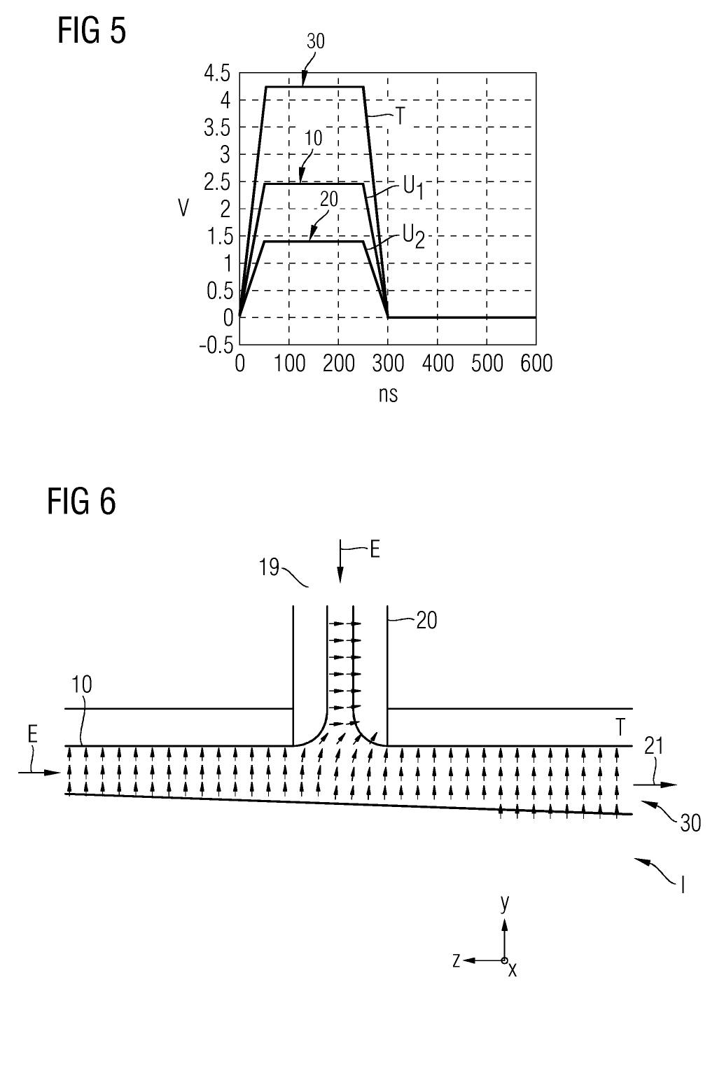

FIG. 6 shows a further representation to simulate the inventive exemplary embodiment of the IVA;

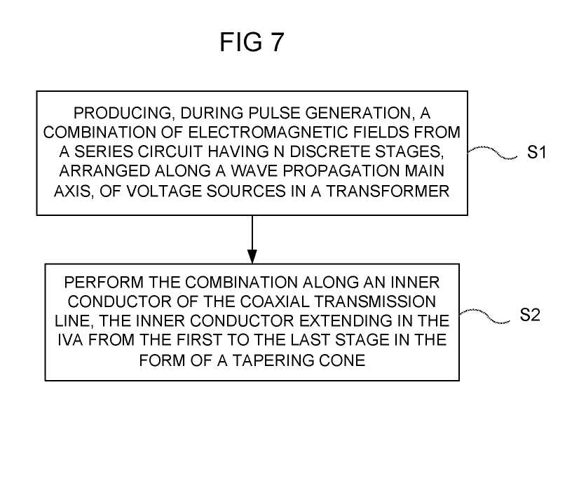

FIG. 7 shows an exemplary embodiment of a method according to the invention.

FIG. 3 shows an inventive exemplary embodiment of an IVA (inductive voltage adder). FIG. 3 shows a continuously conical inner conductor I that replaces a conventional cascaded inner conductor of a coaxial conductor in consideration of characteristic impedance circumstances. In this way, it is possible to dispense with a conventional cascaded inner conductor—manufactured in complex fashion—of the coaxial conductor for an IVA according to the invention, said cascaded inner conductor being able to be replaced in the course of the invention by a conical inner conductor I that is simple to manufacture. FIG. 3 shows an inventive embodiment of the coaxial inner conductor I, which is provided in conical form in the IVA in this case, it being possible to dispense with the conventional, complex individual taper sections. Owing to the selection of a continuously conical coaxial inner conductor I, industrial manufacture can be effectively simplified and made less expensive in comparison with a conventional, cascaded coaxial inner conductor. FIG. 3 shows a schematic representation of the inventive, conical, coaxial inner conductor I. The IVA shown in FIG. 3 extends along a wave propagation main axis HA. A denotes an outer conductor of a coaxial transmission line 21 that is provided by means of the outer conductor A and the inner conductor I. The outer conductor A can be provided as a number of hollow cylinders, these being positioned rotationally symmetrically with respect to the wave propagation main axis HA. S denotes switches that are used to generate voltage pulses associated with a respective stage. FIG. 3 shows an inductive voltage adder having a coaxial inner conductor I of conical design with three stages. The inventive IVA structure can be used to simplify manufacture and to effectively reduce costs when a continuously conical coaxial inner conductor I is used.

FIG. 4 shows a representation to simulate the inventive exemplary embodiment of the IVA. FIG. 4 shows an electromagnetic model of a stage having an embodied conical coaxial inner conductor I. This electromagnetic model has three ports or connections 10, 20 and 30, in particular. As shown in FIG. 4, only an upper side of a cross section of the IVA is considered. The first connection 10 applies a voltage U1 as a supply signal E, said voltage being summed, by means of a port or the second connection 20, with a second supply signal E in the form of a voltage U2 such that a signal that results from the addition of the voltages U1 and U2 is obtained at a third connection 30. This output signal A propagates along a coaxial transmission line 21, with the second supply signal E being coupled in along a radial transmission line 19 at the second connection 20. Electromagnetic field simulations on a stage according to the invention as shown in FIG. 4 surprisingly show neat addition of the supply signals E in the form of the voltages U and U2 in the transformer. FIG. 4 shows a model of the transformer.

FIG. 5 shows a further representation to simulate the inventive exemplary embodiment of the IVA, specifically a time characteristic for the supplied voltage signals U1 and U2 and for an output signal T at the third connection 30 in the time domain when the inventive first stage of an IVA as shown in FIG. 4 is used. This simulation shows the first supply signal E=U1 in the center, the second supply signal E=U2 at the bottom and the output signal T at the top, with the x axis indicating the time in ns and the y axis indicating the voltage in volts.

FIG. 6 shows a representation of the profile of the electric fields in a first stage, according to the invention, of an IVA as shown in FIG. 4. Arrows represent a vector field. FIG. 6 shows electric fields in the transformer of a stage as shown in FIG. 4 with an embodied conical coaxial inner conductor I. On the left-hand side, there is a first supply signal E at a first connection 10 and a second supply signal at a second connection 20, with an output signal T being able to be detected on the right-hand side at a third connection 30. The electric fields are shown as respective vector fields in the region of the voltage addition as shown in FIG. 4. The conical form of the inner conductor I is illustrated by means of a lower line running obliquely horizontally.

Besides the mechanically simpler form of an inner conductor I according to the invention, the electromagnetic field simulations additionally show lower excessive local electrical field intensities in the region of the coupling-in point of the radial transmission line 19. This automatically results in a higher withstand voltage in the transformer of the IVA itself, meaning that the latter requires fewer stages. Similarly, the advantageous withstand voltage diminishes the physical volume of the IVA. Besides the higher withstand voltage, better transmission properties at higher frequencies are likewise obtained with a coaxial inner conductor according to the invention. This allows lower attenuation to be accomplished. In this way, a structure according to the invention is better suited to high-frequency pulses, that is to say pulses with particularly steep rising edges. On a coaxial inner conductor, the electric fields, as a result of Maxwell's equations, are largest. For the inventive embodiments, FIG. 6 clearly reveals the homogeneous field profile for the electric field. This allows lower reflections in comparison with the prior art to be accomplished for transient signals too.

FIG. 7 shows an exemplary embodiment of a method according to the invention. In a first step S1, during the pulse generation there is combination of electromagnetic fields from a series circuit comprising a number n of discrete stages, arranged along a wave propagation main axis, of voltage sources in a transformer. A second step S2 is used to perform the combination along an inner conductor of the coaxial transmission line, said inner conductor extending in the IVA from the first to the last stage in the form of a tapering cone.

The present invention relates to an apparatus and to a method for generating high-voltage pulses, particularly by means of an inductive voltage adder (IVA), wherein an inner conductor (I) of a coaxial transmission line (21) is in the form of a body that is rotationally symmetrical with respect to the wave propagation main axis (HA), passes through all the stages and the outer radius of which is designed to decrease continuously with a constant slope from the first to the last stage.

1-14. (canceled)

15. An apparatus for generating high-voltage pulses, comprising:
an inductive voltage adder, including a transformer having voltage sources arranged along a wave propagation main axis in a series circuit with discrete stages, each stage including a radial transmission line and a coaxial transmission line, whereby waves respectively propagate along the radial transmission line into the coaxial transmission line during the pulse generation producing a combination of electromagnetic fields, the inner conductor of the coaxial transmission line, formed as a body rotationally symmetrical with respect to the wave propagation main axis and passing through all of the discrete stages, having an outer radius decreasing continuously with a constant slope from a first stage to a last stage.

16. The apparatus as claimed in claim 15, wherein the inner conductor has an external geometric shape of at least a portion of a straight cone.

17. The apparatus as claimed in claim 15, wherein the inner conductor has a conical shape.

18. The apparatus as claimed in claim 15, wherein the outer conductor of the coaxial transmission line is a hollow body, rotationally symmetrical with respect to the wave propagation main axis provided discretely in each stage, having identical inner radii and identical outer radii in each stage.

19. The apparatus as claimed in claim 18, wherein the hollow body in each stage is a hollow cylinder.

20. The apparatus as claimed in claim 15, wherein the radial and coaxial transmission lines are constructed of an identical material selected from the group consisting of copper, steel and aluminum.

21. The apparatus as claimed in claim 15, further comprising electrical interconnections between the discrete stages having a modular design identical for all of the discrete stages.

22. A method for generating high-voltage pulses in an inductive voltage adder, comprising:
combining, during pulse generation, electromagnetic fields from a series circuit of discrete stages, arranged along a wave propagation main axis, of voltage sources in a transformer; and
respectively propagating waves along a radial transmission line into a coaxial transmission line in each stage, the inner conductor of the coaxial transmission line, formed as a body rotationally symmetrical with respect to the wave propagation main axis and passing through all of the discrete stages, having an outer radius decreasing continuously with a constant slope from a first stage to a last stage.

23. The method as claimed in claim 22, wherein the inner conductor has an external geometric shape of at least a portion of a straight cone.

24. The method as claimed in claim 22, wherein the inner conductor has a conical shape.

25. The method as claimed in claim 22, wherein the outer conductor of the coaxial transmission line is a hollow body, rotationally symmetrical with respect to the wave propagation main axis provided discretely in each stage, having identical inner radii and identical outer radii in each stage.

26. The method as claimed in claim 25, wherein the hollow body in each stage is a hollow cylinder.

27. The method as claimed in claim 22, wherein the radial and coaxial transmission lines are constructed of an identical material selected from the group consisting of copper, steel and aluminum.

28. The method as claimed in claim 22, wherein all of the discreet stages have a like modular design in respect to electrical interconnections between adjacent stages.
